(19) United States
(12) Patent Application Publication
(10) Pub. No.: US 2006/0152985 A1
(43) Pub. Date: Jul. 13, 2006

(54) Output power testing apparatus for memory

(75) Inventor: Mei-Hui Chen, Taipei (TW)

Correspondence Address: BIRCH STEWART KOLASCH & BIRCH, PO BOX 747, FALLS CHURCH, VA, 22040-0747, US

(73) Assignee: INVENTEC CORPORATION

(21) Appl. No.: 11/236,500

(22) Filed: Sep. 28, 2005

(30) Foreign Application Priority Data
Dec. 29, 2004 (TW) 93141253

(51) Int. Cl. G11C 7/00; G11C 29/00

(52) U.S. Cl. 365/201

(57) ABSTRACT

An output power testing apparatus for memory is provided. The apparatus includes a signal control device and an adjusting voltage circuit. The signal control device is coupled to the adjusting voltage circuit, and the adjusting voltage circuit adjusts the output voltage based on a set of testing signals from the signal control device.

### BACKGROUND

1. Field of Invention

The invention relates to a power testing apparatus, particularly an output power testing apparatus for memory.

2. Related Art

Testing steps are necessary for electronic devices during manufacturing processes, whether they are finished products or half-finished products. Therefore, tests and improvements needed to be repeated for new designed products in order check the quality. Moreover, even for mass production products, they still need to be tested individually before shipment. Additionally, they still need repeated tests on all components and functions, even if only adding a component or a function on a mass production product. Normally, during the tests before shipment, all functions, components, and equipment of an electronic device are tested, so it would cost more testing time if adding more functions or equipment. Therefore, shortening the testing time is a solution for increasing the product capability.

The memory test before shipment needs to observe the stability of the output power. In general, the output power of the memory must keep a fixed value of 2.5V, but the real output power would be an approximate value of 2.5 V due to the affections from the whole circuit designs and the composed components. Nevertheless, it would make the whole system unstable if the output power is too high or too low. More seriously, it would result in failure of the electronic device. Therefore, the output power test is necessary for the memory before shipment, in order to be sure of the stability of the system.

The conventional testing method utilizes a variable resistor (VR) instead of an original voltage divider resistor on the output side, thereafter, it makes the output power in a range of ±0.6V (1.9V˜3.1V), by adjusting the resistance value of the trimmer, then observing the stability of the system. However, doing it this way needs usage of an iron to remove the original voltage divider resistor, then soldering a trimmer on the same location before testing. Therefore, it is not convenient and would cause damage of other components during the removing and soldering steps. Besides, it needs adjusting the trimmer very stable. Otherwise, a little movement would result in different output powers and affect the test results.

### SUMMARY

In consideration of the problems above, the object of the present invention is to provide an output power testing apparatus for memory in order to improve the problems or defects of the conventional methods.

The output power testing apparatus for memory of the present invention utilizes a control IC to change the value of the output power in order to test the stability of the system under the output voltage in a rage of ±0.6V.

Therefore, in order to make the objects above, the output power testing apparatus for memory of the present invention includes a signal control device and an adjusting voltage circuit, coupled to each other.

The adjusting voltage circuit adjusts the output voltage via a set of testing signals from the signal control device. Therefore, the signal control device modulates a high-level or a low-level testing signal, so that the adjusting voltage circuit outputs a high-level or low-level voltage, based on the testing signals.

In one embodiment, the adjusting voltage circuit is an integrated circuit. The signal control device is a connector having a plurality of slots and generating different combinations of testing signals via the number of jumps inserted into the slots and the positions of the inserted slots.

Besides, the output power testing apparatus for memory of the present invention includes a filter circuit and a voltage divider resistor, wherein the voltage divider resistor is coupled parallel to the filter circuit. The filter circuit is used for filtering the output voltage, and the voltage divider resistor is used for dividing voltage. In one embodiment, the filter circuit includes a plurality of identical or different capacitors, which are coupled parallel to each other.

Further scope of applicability of the present invention will become apparent from the detailed description given hereinafter.

### BRIEF DESCRIPTION OF THE DRAWINGS

The present invention will become more fully understood from the detailed description given in the illustration below only, and thus does not limit the present invention, wherein:

FIG. 1 shows a brief construction diagram of a conventional output power circuit for memory;

FIG. 2 shows a brief construction diagram of a conventional output power testing circuit for memory;

FIG. 3 shows a brief construction diagram of an output power testing apparatus according to an embodiment of the present invention; and

FIG. 4 shows a relation chart according to the combinations of testing signals and the output voltage Vo in FIG. 3.

### DETAILED DESCRIPTION OF THE INVENTION

As described below, an embodiment of the present invention is illustrated and references with the figures to describe the present invention in detail. The symbols in the description are referenced by the figures.

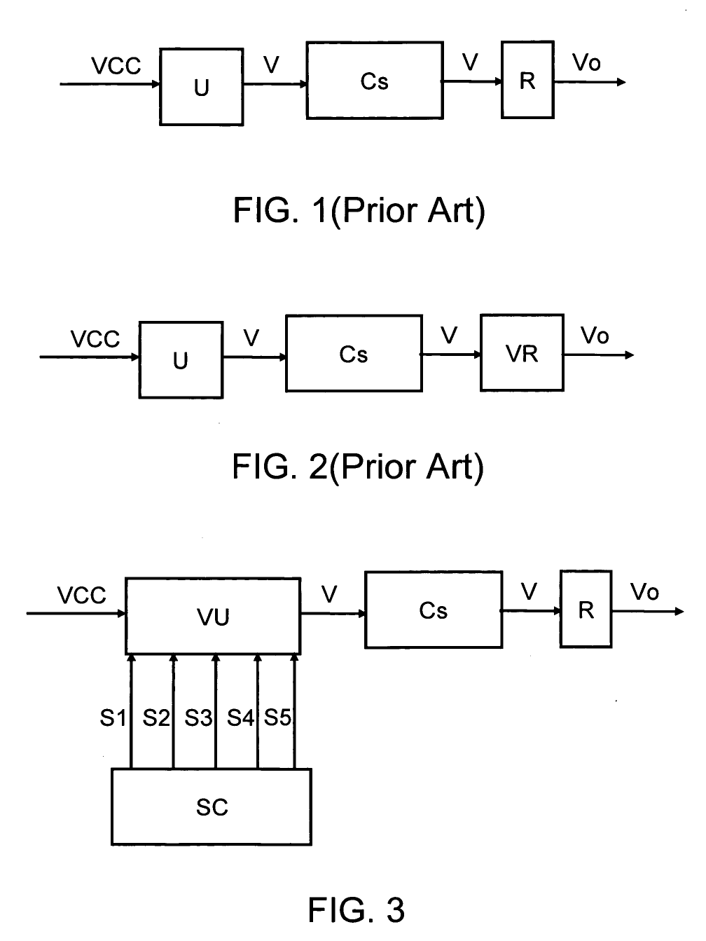

Generally, a memory circuit design includes an integrated circuit U, a filter circuit Cs and a voltage divider resistor R on the memory output side, and they are coupled as in FIG. 1. Hence, the output voltage of the memory would be integrated via the integrated circuit firstly, then integrated via the filter circuit Cs, and finally be divided by the voltage divider resistor R and be outputted. A filter circuit includes a plurality of identical or different capacitors, which are coupled parallel to each other, and the voltage divider resistor is coupled parallel to the filter circuit.

FIG. 2 illustrates a construction diagram of the conventional output power testing circuit, which utilizes a trimmer VR instead of the original voltage divider resistor. Hence, it can change the output voltage via manual adjustment of the resistance value of the trimmer VR by an operator.

FIG. 3 illustrates an output power testing apparatus for memory of the embodiment of the present invention. In this embodiment, an adjusting voltage circuit VU, a filter circuit Cs and a voltage divider resistor R are coupled, additionally, there is a signal control device SC, which is coupled to the adjusting voltage circuit VU. The adjusting voltage circuit VU adjusts the output voltage based on a set of testing signals S1˜S5. More precisely, the adjusting voltage circuit VU outputs high-level or low-level voltage based on the high-level or low-level of the testing signals S1˜S5, wherein the testing signals S1˜S5 are composed via the signal control device SC. In this embodiment, the filter circuit includes a plurality of identical or different capacitors which are coupled parallel to each other, and the adjusting voltage circuit VU is an integrated circuit, for example: the model No. HIP6311 and so on . . . The signal control device SC is a connector having a plurality of slots. A set of testing signals are generated when more than one jump is inserted into the slots. In other words, it can generate a different set of testing signals via the number of jumps inserted into the slots and the positions of the inserted slots.

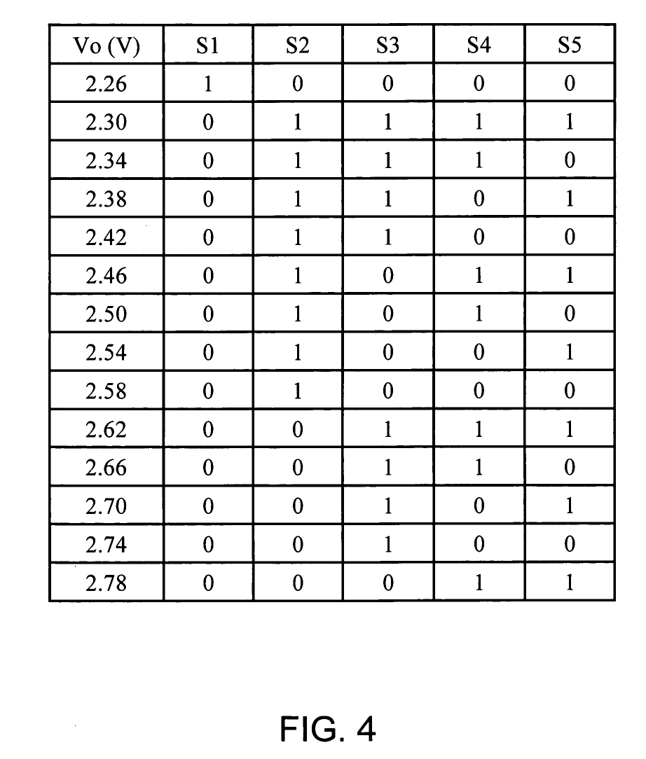

FIG. 3 illustrates an output power testing apparatus for memory of the embodiment of the present invention, wherein the adjusting voltage circuit VU is an integrated circuit, and the signal control device SC is a connector. When the output power testing apparatus applies on a memory circuit for an operator processing an output power test, outputs different levels of testing signals S1˜S5 to the integrated circuit via increasing the number of jumps, which are inserted into the slots on the connector and changing the inserted slots. Thereafter, the integrated circuit in turn modulates the output voltage Vo, based on various sets of testing signals, wherein the relation of the sets of testing signals to the output voltage Vo is shown in FIG. 4; the “1” means a high-level signal, and the “0” means a low-level signal. Hence, the output voltage is different in a range of ±0.6V, and an operator processes a system stability test via adjusting the value of the voltage.

Knowing the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. An output power testing apparatus for memory, comprising:
a signal control device for generating a plurality of testing signals; and
an adjusting voltage circuit coupled to the signal control device for adjusting the output voltage based on the testing signals.

2. The output power testing apparatus for memory as claimed in claim 1, wherein the signal control device comprises:
a connector which has a plurality of slots and which generates the testing signals; and
at least one jump for inserting into the slots to change the testing signals.

3. The output power testing apparatus for memory as claimed in claim 2, wherein the signal control device generates the different testing signals based on the number of the jumps inserted into the slots and the positions of the inserted slots.

4. The output power testing apparatus for memory as claimed in claim 1, wherein the adjusting voltage circuit is an integrated circuit.

5. The output power testing apparatus for memory as claimed in claim 1, wherein further comprises:
a filter circuit coupled to the adjusting voltage circuit for filtering the output voltage from the adjusting voltage circuit; and
a voltage divider resistor coupled in parallel to the filter circuit.

6. The output power testing apparatus for memory as claimed in claim 5, wherein the filter circuit includes a plurality of capacitors coupled in parallel to each other.
